(19) United States
(12) Patent Application Publication
(10) Pub. No.: US 2012/0174568 A1
(43) Pub. Date: Jul. 12, 2012

(54) THERMOELECTRIC DEVICE, MOTOR VEHICLE HAVING THERMOELECTRIC DEVICES AND METHOD FOR MANUFACTURING A THERMOELECTRIC DEVICE

(75) Inventors: ROLF BRÜCK, BERGISCH GLADBACH (DE); SIGRID LIMBECK, MUCH (DE)

(73) Assignee: EMITEC GESELLSCHAFT FUR EMISSIONSTECHNOLOGIE MBH, Lohmar (DE)

(21) Appl. No.: 13/407,005

(22) Filed: Feb. 28, 2012

Related U.S. Application Data
(63) Continuation of application No. PCT/EP2010/060186, filed on Jul. 15, 2010.

(30) Foreign Application Priority Data
Aug. 28, 2009 (DE) 10 2009 039 228.9

(51) Int. Cl. F01N 5/02; H01L 35/34; H01L 35/32

(52) U.S. Cl. 60/320; 136/224; 136/201

(57) ABSTRACT

A thermoelectric device includes at least one first flow duct, at least one second flow duct, at least one first carrier layer associated with the at least one first flow duct and at least one second carrier layer associated with the at least one second flow duct, at least one intermediate space between the first carrier layer and the second carrier layer and a plurality of p and n-doped semiconductor elements disposed in the at least one intermediate space and electrically interconnected. A relative first thermal expansion of the first carrier layer and a relative second expansion of the second carrier layer are equal under operating conditions. Suitable materials are provided for the first and second carrier layers that promote the use of such thermoelectric devices in exhaust systems of a motor vehicle. A motor vehicle having thermoelectric devices and a method for manufacturing a thermoelectric device are also provided.

### CROSS-REFERENCE TO RELATED APPLICATION

This is a continuation, under 35 U.S.C. §120, of copending International Application No. PCT/EP2010/060186, filed Jul. 15, 2010, which designated the United States; this application also claims the priority, under 35 U.S.C. §119, of German Patent Application DE 10 2009 039 228.9, filed Aug. 28, 2009; the prior applications are herewith incorporated by reference in their entirety.

### BACKGROUND OF INVENTION

1. Field of the Invention

The present invention relates to a thermoelectric device for generating electrical energy, for example from the exhaust gas of an internal combustion engine, through the use of a thermoelectric generator. The thermoelectric generator is, in particular, a generator for converting thermal energy of exhaust gas into electrical energy. The invention also relates to a motor vehicle having thermoelectric devices and a method for manufacturing a thermoelectric device.

Exhaust gas from an engine of a motor vehicle has thermal energy which can be converted into electrical energy through the use of a thermoelectric generator or apparatus in order, for example, to charge a battery or some other energy storage device or feed required energy directly to electrical loads. The motor vehicle is therefore operated with a better energy efficiency level and energy is available to a relative large extent for the operation of the motor vehicle.

Such a thermoelectric generator has at least a plurality of thermoelectric converter elements. Thermoelectric converter elements are of a type that can convert the effectively thermal energy into electrical energy (Seebeck effect) and vice versa (Peltier effect). The “Seebeck effect” is based on the phenomenon of the conversion of thermal energy into electrical energy and is used to generate thermoelectric energy. The “Peltier effect” is the converse of the “Seebeck effect” and is a phenomenon which involves thermal adsorption and is caused by different materials in association with a flow of current. The “Peltier effect” has already been proposed, for example, for the purpose of thermoelectric cooling.

Such thermoelectric converter elements preferably have a plurality of thermoelectric elements which are positioned between a so-called hot side and a so-called cold side. Thermoelectric elements include, for example, at least two semiconductor elements (p-doped and n-doped) which are provided alternately with electrically conductive bridges on their upper side and lower side (toward the hot side and/or cold side). Ceramic plates or ceramic coatings and/or similar materials serve to electrically insulate the metal bridges and are therefore preferably disposed between the metal bridges. If a temperature gradient is made available on each side of the semiconductor elements, a voltage potential is formed. In this context, heat is taken up on the hot side of the first semiconductor element, wherein the electrons at one side pass to the energetically higher conduction band of the following semiconductor element. On the cold side, the electrons can then release energy and migrate to the following semiconductor element with a relatively low energy level. A flow of electric current can therefore occur given a corresponding temperature gradient.

The large temperature difference which occurs between the hot side and the cold side in a thermoelectric generator in an exhaust system of a motor vehicle puts the materials used and their structure under heavy stress. The temperatures in a thermoelectric generator on the cold side in an exhaust system are typically between 20° C. and 110° C., and between 150° C. and 500° C. on the hot side. The large temperature difference leads to different degrees of expansion of the materials on the hot side and on the cold side. The different degrees of expansion in turn lead to stresses in the thermoelectric generator, which over time can adversely affect the coherence and/or the functioning of the generator. Compensation elements have already been proposed in the thermoelectric generator in order to reduce the stresses. However, an additional compensation element in a thermoelectric generator increases the technical expenditure during its manufacture.

### SUMMARY OF THE INVENTION

It is accordingly an object of the invention to provide a thermoelectric device, a motor vehicle having thermoelectric devices and a method for manufacturing a thermoelectric device, which overcome the hereinafore-mentioned disadvantages and at least partially solve the highlighted problems of the heretofore-known devices, vehicles and methods of this general type. In particular, a thermoelectric device is to be specified which is adapted for use in a thermoelectric generator in an exhaust system. The thermoelectric device is to be capable of reducing thermal stresses between the hot side and the cold side despite the temperature difference during operation.

With the foregoing and other objects in view there is provided, in accordance with the invention, a thermoelectric device, comprising at least one first flow duct and at least one second flow duct, at least one first carrier layer associated with the at least one first flow duct and at least one second carrier layer associated with the at least one second flow duct, the at least one first carrier layer and the at least one second carrier layer defining at least one intermediate space therebetween, and a plurality of p-doped and n-doped semiconductor elements disposed in the at least one intermediate space and electrically connected to one another. The at least one first carrier layer has a relative first thermal expansion and the at least one second carrier layer has a relative second expansion. The relative first and second expansions are the same under operating conditions.

The thermoelectric device proposed herein is disposed, in particular, between an individual first flow duct and an individual second flow duct, or between a multiplicity of first flow ducts and a multiplicity of second flow ducts. Fluids, that is to say gases or liquids, are respectively conducted through the flow ducts on each side of the device. One side of a thermoelectric device is referred to as a hot side, wherein hot fluid flows through the flow ducts which are assigned to the hot side. The other side of a thermoelectric device is accordingly referred to as a cold side, wherein a fluid at a relatively low temperature flows through the flow ducts which are assigned to the cold side. It is always assumed below that the at least one first flow duct forms the hot side and the at least one second flow duct forms the cold side. However, this can also be generally interchanged. In the text which follows, the first carrier layer is assigned to the hot side and the second carrier layer is assigned to the cold side, without, however, limiting the invention to this assignment. In a motor vehicle, the hot side is normally assigned to the gases of an exhaust system, and the cold side is assigned to the liquid of a cooling circuit.

In particular, the first carrier layer which is assigned to the at least one first flow duct and the second carrier layer which is assigned to the at least one second flow duct at least partially form the boundary of the respective flow ducts, that is to say for example part of the wall of individual flow ducts or of plural flow ducts. The first carrier layer and the second carrier layer are therefore thermally connected to the fluid of the hot side or to the fluid of the cold side. In this way, a temperature gradient is transmitted to the semiconductor elements which are disposed between the carrier layers and which can generate a current on the basis of the “Seebeck effect”.

The carrier layers consequently form the boundary of the thermoelectric device. An intermediate space in which the semiconductor elements are disposed is provided between the carrier layers. The intermediate space therefore has in particular an extent which is predefined substantially only by a height and a number as well as by the configuration of the semiconductor elements. In order to implement a selected flow of current through the p-doped and n-doped semiconductor elements, the carrier layers can each at least partially have an electrical insulation layer to which the semiconductor elements are secured and connected to one another electrically. In the case of the electrical insulation layer it is necessary to ensure that it does not excessively impede the transfer of heat from an outer side of the carrier layer to the semiconductor elements.

For example, bismuth tellurite (Bi₂Te₃) can be used as the conductive materials for the p-doped and n-doped semiconductor elements. Furthermore, the following materials [up to the following maximum temperatures in ° C.] could be used:

n-type:

Bi₂Te₃ [approx. 250° C.]; PbTe [approx. 500° C.]; Ba_{0,3}Co_{3,95}Ni_{0,05}Sb₁₂ [approx. 600° C.]; Ba_{y}(Co,Ni)₄Sb₁₂ [approx. 600° C.]; CoSb₃ [approx. 700° C.]; Ba₈Ga₁₆Ge₃₀ [approx. 850° C.]; La₂Te₃ [approx. 1100° C.]; SiGe [approx. 1000° C.]; Mg₂(Si,Sn) [approx. 700° C.];

p-type:

(Bi,Sb)₂TE₃ [approx. 200° C.]; Zn₄Sb₃ [approx. 380° C.]; TAGS [approx. 600° C.]; PbTe [approx. 500° C.]; SnTe [approx. 600° C.]; CeFe₄Sb₁₂ [approx. 700° C.]; Yb₁₄MnSb₁₁ [approx. 1000° C.]; SiGe [approx. 1000° C.]; Mg₂(Si,Sb) [approx. 600° C.].

In the thermoelectric device according to the invention, the two carrier layers are therefore used to bound the intermediate space and for a transfer of heat from the flow ducts to the semiconductor elements. The semiconductor elements can be made available in this case, for example, in the manner of small rectangular parallel-epipeds composed of materials with differing electrical conductivity. In each case, two different semiconductor elements (p-doped and n-doped) are preferably connected electrically to one another in such a way that together they form a series circuit. One of the two carrier layers absorbs the inflowing thermal current (hot side) while the other carrier layer outputs the outflowing thermal current (cold side). With respect to the layout of the configuration or the wiring of the individual semiconductor elements, the type, construction and/or position of the semiconductor elements can be adapted to the installation space, the desired thermal current, the guide routing of the current etc., wherein they can, in particular, also differ in this case. In particular, the thermoelectric device has one or more groups of semiconductor elements which are connected in series with one another, wherein the groups each form circuits which are independent of one another or are connected to one another through an electrical parallel circuit.

The relative thermal expansion results from the product of an averaged coefficient of expansion of the carrier layer and the difference in temperature which this carrier layer is subjected to, under operating conditions of the thermoelectric device. The averaged coefficient of expansion is the quotient formed from a change in length in the case of a temperature rise in the overall length at a resting temperature. The unit of the averaged coefficient of expansion is 1/Kelvin. The change in length during the determination of the averaged coefficient of expansion is defined herein as the difference between the length of the carrier layer at the resting temperature and the length of the carrier layer at the (maximum) operating temperature. The difference in temperature results from the difference between the (maximum) operating temperature and the resting temperature (under operating conditions).

The resting temperature both for the first carrier layer and for the second carrier layer is typically between −20° C. and 40° C., preferably between 0° C. and 20° C., particularly preferably precisely 10° C. The (maximum) operating temperature of a hot side is between 150° C. and 900° C., preferably between 250° C. and 700° C., particularly preferably precisely 325° C. (for thermoelectric devices in an exhaust gas recirculation system) or precisely 625° C. (for thermoelectric devices in an exhaust system on the underbody of a vehicle). The operating temperature of a cold side is between −20° C. and 120° C., preferably between 50° C. and 80° C., particularly preferably precisely 65° C. Possible measuring methods for determining the change in length are known to a person skilled in the art. The measurements are preferably carried out at the particularly preferred temperatures.

Given an “identical” configuration of the relative first thermal expansion of the first carrier layer and the relative second thermal expansion of the second carrier layer, the values only insignificantly differ from one another, in particular with a tolerance of (on average or even in absolute terms) at maximum 10%, in particular at maximum 1.0% or even only at maximum 0.1%.

This makes it clear in particular that the first carrier layer and the second carrier layer have different averaged coefficients of expansion in order to form an identical configuration of the relative thermal expansions. According to the invention, the large temperature difference between the first carrier layer and the second carrier layer, which normally results in different degrees of expansion of these components, is therefore compensated during operation or under operating conditions due to the adapted averaged coefficients of expansion. In this context, the relatively small relative thermal expansion should lie within the specified tolerance range of the relatively large thermal expansion.

In accordance with another feature of the thermoelectric device of the invention, the first carrier layer has a coefficient of expansion of 2*10⁻⁶/K to 10.2*10⁻⁶/K and the second carrier layer has a coefficient of expansion of 12*10⁻⁶/K to 28.4*10⁻⁶/K. For technical reasons to do with measurement, the specified coefficients of expansion may be subject to an error of up to 5% and are specified as “averaged” values.

It is quite particularly preferred in this case that the first carrier layer has a coefficient of expansion of 5.5*10⁻⁶/K to 8*10⁻⁶/K and the second carrier layer has a coefficient of expansion of 18*10⁻⁶/K to 28.4*10⁻⁶/K.

As a result of the selection of an alloy with the preferred expansions of coefficient, the first carrier layer has a coefficient of expansion which virtually corresponds to that of the semiconductor elements, and given a temperature difference of up to approximately 450° C. during operation, the second carrier layer expands to precisely the same degree as the carrier layer of the hot side. Tests and analyses have shown that with such materials it is possible to make available a thermoelectric device which is particularly low in stress and therefore has a long service life even under alternating stress.

In order to determine the coefficient of expansion of the material used for the first carrier layer or for the second carrier layer, a test strip of the material, which can be obtained either by removal from the thermoelectric device or as a raw material, can firstly be clamped in on one side. The test strip is heated to a (maximum) operating temperature by applying a suitable material to it after the measurement at the resting temperature. If the test strip is subjected to the medium for sufficiently long, with the result that the test strip has entirely assumed the temperature of the medium, the length of the strip is measured in at least one dimension. In the text which follows, the temperature of the medium is selectively increased by several degrees and after a time in which the test strip assumes the increase in temperature, the length of the test strip is measured once again. The coefficient of expansion can be determined from the length, the difference in the measurement of length and the difference in temperature.

With respect to the use of such a device in an exhaust gas recirculation system, the operating temperature of the cold side is typically between 50° C. and 80° C. (in particular precisely 65° C.) and that of the hot side is between 250° C. and 400° C. (in particular precisely 325° C.). In order to carry out the measurement of the coefficient of expansion of a material of the cold side, a water bath with a suitable heating plate can be used with which the temperature of the water bath can be regulated as precisely as possible. In addition, it is possible to imagine that the test strip is subjected to a stream of fluid, in particular a gas stream having a temperature which can be controlled in a monitored fashion. Such a hot stream of fluid is also suitable for measuring a material on the hot side. A material on the hot side can, however, also be heated in an oven having a temperature which can be controlled very precisely.

In accordance with a further preferred feature of the thermoelectric device of the invention which can, however, also be independently considered to be inventive, at least the first carrier layer or the second carrier layer is composed of an alloy containing:
a proportion of nickel of at least 9.0% by weight,
a proportion of silicon of at most 1.0% by weight, and
at least one element from the group of manganese, chromium, carbon, molybdenum, cobalt, aluminum, titanium, copper and niobium and iron.

The advantageous alloy has a wide range of the coefficient of expansion with otherwise similar mechanical and thermal properties. The coefficient of expansion of the alloy according to the invention extends from 1.0*10⁻⁶/K to 31.7*10⁻⁶/K in a temperature range from 20° C. to 500° C. The wide range of the coefficient of expansion permits the alloy of the carrier layers to be adapted both to the given operating temperatures and to the material properties of the semiconductor elements being used. The coefficient of expansion can be influenced to a considerable degree through the use of the proportion of nickel in the alloy. An iron/nickel alloy with a proportion of nickel of 36% by weight therefore has a minimum of the coefficient of expansion. Through the proportion of silicon in the alloy, the tensile strength and the elastic limit thereof can be influenced to a considerable degree. In addition to the proportions of material specified according to the invention, the alloy can also have typical impurities, which are however insignificant in this case.

At least the first carrier layer or the second carrier layer is composed of an advantageous alloy. However, it is preferred that both the first carrier layer and the second carrier layer are embodied with the alloy according to the invention.

A suitable selection of the alloys according to the invention for the first carrier layer and/or the second carrier layer ensures that the absolute expansions of the first carrier layer and that of the second carrier layer during operation of the device are of similar magnitude, although there may be a difference in temperature of up to 450° C. In this way, virtually no (significant) stresses occur between the first carrier layer and the second carrier layer. This means, in particular, that points on the inner face of the first carrier layer and points on the inner face of the second carrier layer, having connecting lines which lie orthogonally with respect to the inner faces in a state without a difference in temperature, maintain virtually the same distance in a state with a large difference in temperature.

In one particularly preferred embodiment, the alloy of the first carrier layer experiences similar expansion during operation to the semiconductor elements and to the alloy of the second carrier layer.

In accordance with an added feature of the thermoelectric device of the invention, the first carrier layer includes a first alloy containing:
a proportion of nickel of at least 32.0% by weight; and
a proportion of manganese of at most 1.0% by weight, as well as
at least one element from the group silicon, chromium, carbon, molybdenum, cobalt, aluminum, titanium and niobium and iron.

The first alloy of this development has a coefficient of expansion of 2.0*10⁻⁶/K to 10.2*10⁻⁶/K in a temperature range from 200° C. to 500° C. The low coefficient of expansion in this temperature range of the first alloy makes it possible to use the first alloy as a material for the carrier layer on the hot side at relatively high temperatures.

In accordance with an additional advantageous feature of the thermoelectric device of the invention, the first carrier layer is composed of a first alloy in which:
the proportion of nickel is between 28.0% by weight and 30.0% by weight;
the proportion of cobalt is between 16.0% by weight and 18.0% by weight;
the proportion of chromium is at most 0.1% by weight;
the proportion of carbon is at most 0.05% by weight;
the proportion of manganese is at most 0.5% by weight;
the proportion of silicon is at most 0.3% by weight; and
the rest is formed of iron and unavoidable impurities.

This alloy specified above is also referred to below as the “preferred hot side material.”

Since this first alloy has a coefficient of expansion between 5.8*10⁻⁶/K and 6.1*10⁻⁶/K in the temperature range between 200° C. and 500° C., the first alloy is advantageously adapted to the coefficient of expansion of suitable semiconductor elements. It is particularly advantageous if the first alloy is used as a carrier layer on the hot side.

The grain growth at relatively high temperatures is inhibited by cobalt. The tempering resistance and heat resistance are therefore improved. On the other hand, cobalt promotes graphite formation. When the concentration is increased, the thermal conductivity is also increased. Chromium increases the tensile strength of the alloys with slight degradation of the expansion. Relatively high chromium contents improve the heat resistance.

It may also be advantageous if the first carrier layer is composed of a first alloy in which the proportion of nickel is between 32.0% by weight and 37.0% by weight, the proportion of manganese is at most 0.6% by weight and at least one element from the group of silicon, chromium, cobalt, titanium and niobium and iron is included. The first alloy is defined by a coefficient of expansion of 2.0*10⁻⁶/K to 10.2*10⁻⁶/K in a temperature range from 200° C. to 500° C. These alloys are therefore particularly suitable for the carrier layer of the hot side. Molybdenum increases the tensile strength and particularly the heat resistance. When alloyed together with chromium and nickel, high elastic limits and strength values can be achieved.

It is likewise possible that the first carrier layer is composed of a first alloy in which the proportion of nickel is between 37.0% by weight and 43.5% by weight, the proportion of manganese is at most 1.0% by weight, the proportion of silicon is at most 0.4% by weight and the proportion of carbon is at most 1.0% by weight, and no aluminum, molybdenum and copper is included. The first alloy is defined by a coefficient of expansion of 3.5*10⁻⁶/K to 9.3*10⁻⁶/K in a temperature range from 200° C. to 500° C. This alloy is therefore particularly suitable for the carrier layer of the hot side.

It is also advantageous if the first carrier layer is composed of a first alloy in which the proportion of nickel is between 45.0% by weight and 52.0% by weight, the proportion of manganese is at most 0.8% by weight, the proportion of silicon is at most 0.5% by weight and at least one element from the group carbon, chromium and aluminum and iron is included. The first alloy is defined by a coefficient of expansion of 8.0*10⁻⁶/K to 10.0*10⁻⁶/K in a temperature range from 200° C. to 500° C. These alloys are therefore particularly suitable for the carrier layer of the hot side and can advantageously be combined with semiconductor elements which have a corresponding coefficient of expansion.

It is also advantageous if the first carrier layer is composed of a first alloy in which the proportion of nickel is between 41.0% by weight and 43.5% by weight, the proportion of manganese is at most 0.6% by weight, the proportion of silicon is at most 1.0% by weight and the proportion of the chromium is at most 6.0% by weight, and at least one element from the group aluminum, cobalt and titanium and iron is included. The first alloy is defined by a coefficient of expansion of 7.3*10⁻⁶/K to 14.4*10⁻⁶/K in a temperature range of 200° C. to 500° C.

It is also advantageous if the second carrier layer is composed of a second alloy in which:
the proportion of nickel is between 12.5% by weight and 23.0% by weight;
the proportion of manganese is at most 7.0% by weight;
the proportion of silicon is at most 1.0% by weight;
the proportion of carbon is 0.65% by weight; and
chromium and iron are possibly included.

This alloy is defined by a coefficient of expansion of 18.9*10⁻⁶/K to 20.7*10⁻⁶/K in a temperature range from 20° C. to 200° C. This alloy is therefore suitable for the carrier layer of the cold side if the difference in expansion between the hot side and the cold side is compensated by a coefficient of expansion of this magnitude. In this way, the absolute expansions of the second carrier layer, which is in thermal contact with the cold side, and that of the first carrier layer, which is in thermal contact with the hot side, are virtually the same even when there are very large temperature differences.

In accordance with yet another advantageous feature of the thermoelectric device of the invention, the second carrier layer is composed of a second alloy in which:
the proportion of nickel is between 9.0% by weight and 11.0% by weight;
the proportion of copper is between 17.0% by weight and 19.0% by weight;
the proportion of iron is at most 1.0% by weight;
the proportion of carbon is at most 0.1% by weight;
the proportion of silicon is at most 0.25% by weight; and the rest is composed of manganese.

This second alloy, which is specified above, is also referred to hereinbelow as the “preferred cold side material.”

This alloy according to the invention has a coefficient of expansion of between 26.8*10⁻⁶/K and 28.4*10⁻⁶/K in a temperature range of between 20° C. and 200° C. Due to the high coefficient of expansion, the alloy is particularly suitable for forming the second carrier layer which is in thermal contact with the cold side.

The combination in which the “preferred hot side material” forms the first carrier layer and the “preferred cold side material” forms the second carrier layer is particularly preferred. In this way, the first carrier layer has a coefficient of expansion which virtually corresponds to the semiconductor elements, and given a temperature difference of up to 450° C. during operation, the second carrier layer expands to precisely the same degree as the carrier layer of the hot side.

In accordance with yet a further preferred feature of the thermoelectric device of the invention, the first carrier layer and the second carrier layer are shaped cylindrically and are disposed concentrically with respect to one another. Cylindrically shaped means an elongated body which has a circle-like cross section. In particular, the cross section is not precisely a circle but rather can also be elliptical. In addition, a pipe with a rectangular cross section can also be used. The first carrier layer and the second carrier layer are formed in such a way that when the first carrier layer forms the inner carrier layer, the outer side of the first carrier layer is at the same distance from the inner side of the second carrier layer virtually everywhere. In such a cylindrical configuration, the inner face of the first carrier layer forms the at least first flow duct and the outer face of the second carrier layer forms part of the boundary of the at least second flow duct. A type of concentric double pipe is therefore formed, wherein a thermoelectric generator can include a plurality of such pipes. Flow ducts for one of the fluids are then formed within the double pipes, while at least one flow duct for the other fluid is formed outside the double pipes.

With the objects of the invention in view, there is also provided a motor vehicle, comprising an internal combustion engine, an exhaust system, a cooling circuit, and at least one thermal generator having a plurality of thermoelectric devices according to the invention, the at least one first flow duct being connected to the exhaust system and the at least one second flow duct being connected to the cooling circuit.

With the objects of the invention in view, there is additionally provided a method for manufacturing a thermoelectric device. The method comprises:
providing a first carrier layer composed of an alloy containing a proportion of nickel of at least 9.0% by weight, a proportion of silicon of at most 1.0% by weight and at least one element from the group consisting of manganese, chromium, carbon, molybdenum, cobalt, aluminum, titanium, copper, niobium and iron;
providing a first electrical insulation layer for the first carrier layer;
providing a second carrier layer composed of an alloy having a proportion of nickel of between 9.0% by weight and 11.0% by weight, a proportion of copper of between 17.0% by weight and 19.0% by weight, a proportion of iron of at most 1.0% by weight, a proportion of carbon of at most 0.1% by weight, a proportion of silicon of at most 0.25% by weight and a remainder composed of manganese;
providing a second electrical insulation layer for the second carrier layer;
placing a plurality of p-doped and n-doped semiconductor elements between the first carrier layer and the second carrier layer; and
mounting the first carrier layer and the second carrier layer with the semiconductor elements disposed therebetween.

With the objects of the invention in view, there is concomitantly provided a method for manufacturing a thermoelectric device. The method comprises:
providing a first carrier layer composed of an alloy having a proportion of nickel of at least 32.0% by weight, a proportion of manganese of at most 1.0% by weight and containing no copper;
providing a first electrical insulation layer for the first carrier layer;
providing a second carrier layer composed of an alloy having a proportion of nickel of between 9.0% by weight and 11.0% by weight, a proportion of copper of between 17.0% by weight and 19.0% by weight, a proportion of iron of at most 1.0% by weight, a proportion of carbon of at most 0.1% by weight, a proportion of silicon of at most 0.25% by weight and a remainder composed of manganese;
providing a second electrical insulation layer for the second carrier layer;
placing a plurality of p-doped and n-doped semiconductor elements between the first carrier layer and the second carrier layer; and
mounting the first carrier layer and the second carrier layer with the semiconductor elements disposed therebetween.

The enumeration of the individual steps is not to be understood in the sense of a series, rather it is possible to repeat, combine and/or interchange multiple steps.

Firstly, a first carrier layer composed of an alloy according to the invention is made available, wherein the carrier layer can be composed of round and/or rectangular plates, but it is also possible to use a pipe as a first carrier layer. The cross section of the pipe is preferably similar to a circle but can also be elliptical in shape. In addition, a pipe with a rectangular cross section is also conceivable.

The electrical insulation layer is preferably applied to the first carrier layer using an immersion bath, a screen printing method, a sputtering method or some other method. The electrical insulation layer is preferably composed in this case of a dielectric, particularly preferably of SiO₂.

A multiplicity of p-doped and n-doped semiconductor elements which can have, for example, a rectangular parallelepiped shape or else can also have an annular shape, are electrically connected to one another and connected in particular alternately in series. The p-doped and n-doped semiconductor elements are wired, in particular through the use of electrically conductive connections, in such a way that they can generate a current as thermoelectric elements. The semiconductor elements can already be p-doped and/or n-doped before the configuration, but they can also receive at least one doping (p or n) after the actual configuration process.

The second carrier layer is formed in this case, in particular, from the “preferred cold side material” and an electrical insulation layer is applied thereto. Subsequently, the first carrier layer, preferably formed with the “preferred hot side material” and the second carrier layer are joined in such a way that the semiconductor elements are disposed between the first carrier layer and the second carrier layer. The mounting can be carried out through the use of brazing, soldering, welding or other joining methods and also using securing devices such as frames, plug-type connections or screws.

Furthermore, the use of a first alloy according to the “preferred hot side material” and/or the use of a second alloy according to the “preferred cold side material” is considered particularly advantageous for accommodating semiconductor elements in a thermoelectric generator. Reference can be made to the entire disclosure with respect to the particular possibilities of use.

Other features which are considered as characteristic for the invention are set forth in the appended claims, noting that the features which are individually specified in the claims can be combined with one another in any desired technically appropriate way and indicate further refinements of the invention.

Although the invention is illustrated and described herein as embodied in a thermoelectric device, a motor vehicle having thermoelectric devices and a method for manufacturing a thermoelectric device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, longitudinal-sectional view of a thermoelectric device; and

FIG. 2 is a diagrammatic and schematic view of a motor vehicle with a thermoelectric device.

### DETAILED DESCRIPTION OF THE INVENTION

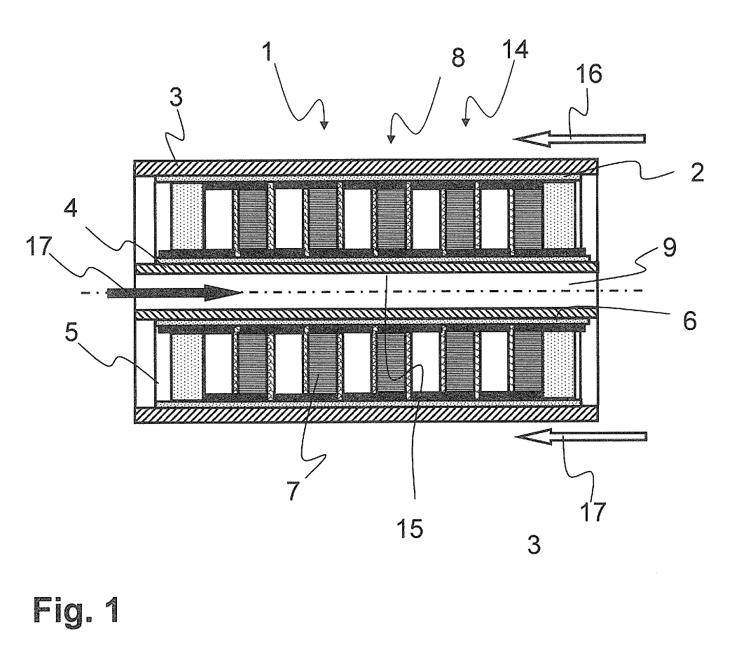

Referring now to the figures of the drawings in detail and first, particularly, to FIG. 1 thereof, there is seen a cylindrical configuration of a thermoelectric device 1 in a sectional illustration through a longitudinal axis thereof. In this exemplary embodiment, a first carrier layer 3 forms an outer sheath which is in thermally conductive contact with a first fluid 16 and therefore forms part of a boundary of a first flow duct 8. A first insulation layer 2, which electrically insulates the first carrier layer 3 from semiconductor elements 7, but hardly influences the flow of heat between the first carrier layer 3 and the semiconductor elements 7, is located on the inner side of the first carrier layer 3. The semiconductor elements 7 are disposed in an intermediate space 5 between the first carrier layer 3 and a second carrier layer 4. The p-doped and n-doped semiconductor elements 7 are disposed alternately between the first insulation layer 2 and a second insulation layer 6, electrically connected to one another and connected in series. The second insulation layer 6 forms electrical insulation of the semiconductor elements 7 from the second carrier layer 4. The second carrier layer 4 is in thermally conductive contact with a second fluid 17 and in this exemplary embodiment forms a second flow duct 9. Either the first flow duct 8 or the second flow duct 9 can form a hot side 14, so that either the second flow duct 9 or the first flow duct 8 forms a cold side 15.

In the exemplary embodiment (for an exhaust gas recirculation system), at least the first carrier layer 3 or the second carrier layer 4 is composed of an alloy according to the invention. The alloy of the other (second or first) carrier layer can be composed of another material. In one embodiment, the alloys from which the first carrier layer 3 and the second carrier layer 4 are composed are selected in such a way that the expansion of the first carrier layer 3 with respect to the second carrier layer 4 is compensated when there is a difference in temperature. In this context, temperatures during operation are between 20° C. and 110° C., typically between 50° C. and 80° C., on the cold side 15, and between 150° C. and 500° C., typically between 250° C. and 400° C., on the hot side 14.

In a further advantageous embodiment, the alloy for the first carrier layer 3 on the hot side 14 is selected in such a way that the coefficient of expansion of the alloy corresponds virtually to the coefficient of expansion of the semiconductor elements 7. In this way, no stresses arise between the first carrier layer 3 and the semiconductor elements 7 when there is a change in temperature. The alloy for the second carrier layer 4 on the cold side 15 is selected in such a way that despite the relatively low temperature, it expands to the same degree as the first carrier layer 3 during operation.

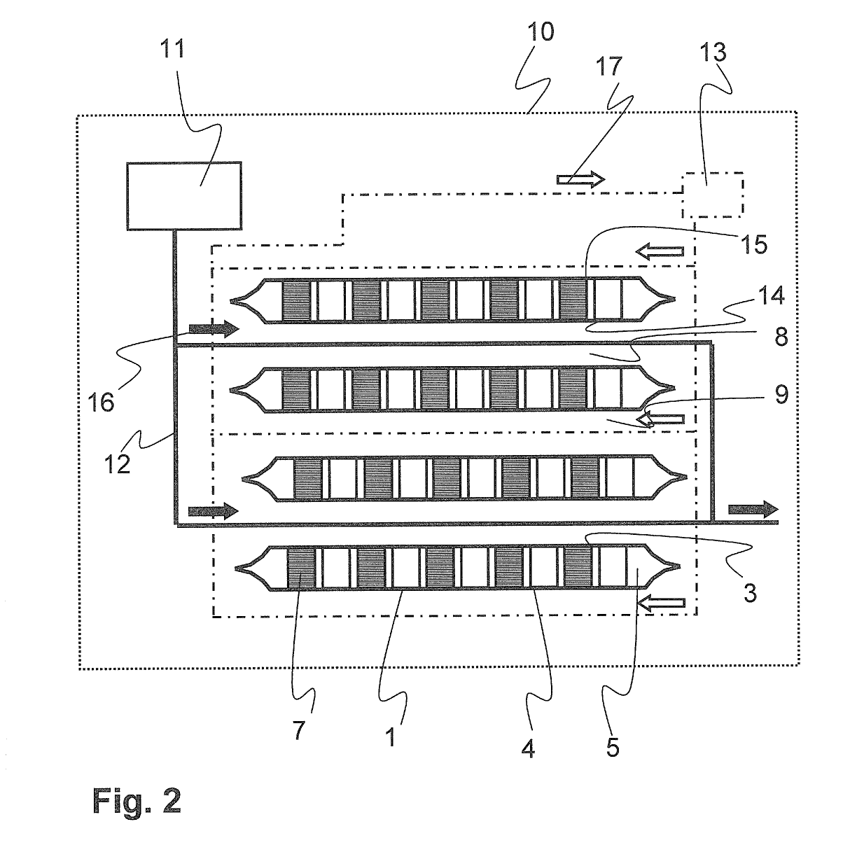

FIG. 2 is a diagrammatic and schematic view of a motor vehicle 10 with a thermoelectric device 1, an internal combustion engine 11, an exhaust system 12 and a cooling circuit 13. The internal combustion engine 11 is connected to the exhaust system 12 and provides a first fluid 16 which brings about a hot side 14 and flows through a first flow duct 8. The cooling circuit 13 provides a second fluid 17 which brings about a cold side 15 and is conducted through a second flow duct 9. It is possible in this context to form a plurality of first flow ducts 8 and second flow ducts 9, with thermoelectric devices 1 disposed therebetween.

The thermoelectric devices 1 are disposed between the flow ducts. In this context, the first carrier layer 3 is in thermally conductive contact with the first fluid 16, which forms the hot side 14, and the second carrier layer 4 is in thermally conductive contact with the second fluid 17, which forms the cold side 15. The semiconductor elements 7 are disposed in an intermediate space 5 between the first carrier layer 3 and the second carrier layer 4. The semiconductor elements 7 generate a current due to the difference in temperature between the hot side 14 and the cold side 15 (according to the “Seebeck effect”). The alloys of the first carrier layer 3 and the alloys of the second carrier layer 4 are selected in this case in such a way that their degrees of thermal expansion at different temperatures compensate one another.

1. A thermoelectric device, comprising:
at least one first flow duct and at least one second flow duct;
at least one first carrier layer associated with said at least one first flow duct and at least one second carrier layer associated with said at least one second flow duct;
said at least one first carrier layer and said at least one second carrier layer defining at least one intermediate space therebetween; and
a plurality of p-doped and n-doped semiconductor elements disposed in said at least one intermediate space and electrically connected to one another;
said at least one first carrier layer having a relative first thermal expansion and said at least one second carrier layer having a relative second expansion, said relative first and second expansions being the same under operating conditions.

2. The thermoelectric device according to claim 1, wherein said at least one first carrier layer has a coefficient of expansion of 2*10⁻⁶/K to 10.2*10⁻⁶/K and said at least one second carrier layer has a coefficient of expansion of 12*10⁻⁶/K to 28.4*10⁻⁶/K.

3. The thermoelectric device according to claim 1, wherein at least said at least one first carrier layer or said at least one second carrier layer is composed of an alloy containing a proportion of nickel of at least 9.0% by weight, a proportion of silicon of at most 1.0% by weight and at least one element from the group consisting of manganese, chromium, carbon, molybdenum, cobalt, aluminum, titanium, copper, niobium and iron.

4. The thermoelectric device according to claim 1, wherein said at least one first carrier layer is composed of an alloy having a proportion of nickel of at least 32.0% by weight, a proportion of manganese of at most 1.0% by weight and containing no copper.

5. The thermoelectric device according to claim 1, wherein said at least one first carrier layer is composed of an alloy having a proportion of nickel of between 28.0% by weight and 30.0% by weight, a proportion of cobalt of between 16.0% by weight and 18.0% by weight, a proportion of chromium of at most 0.1% by weight, a proportion of carbon of at most 0.05% by weight, a proportion of manganese of at most 0.5% by weight and a proportion of silicon of at most 0.3% by weight.

6. The thermoelectric device according to claim 1, wherein said at least one second carrier layer is composed of an alloy having a proportion of nickel of between 9.0% by weight and 11.0% by weight, a proportion of copper of between 17.0% by weight and 19.0% by weight, a proportion of iron of at most 1.0% by weight, a proportion of carbon of at most 0.1% by weight, a proportion of silicon of at most 0.25% by weight and a remainder composed of manganese.

7. The thermoelectric device according to claim 1, wherein said at least one first carrier layer and said at least one second carrier layer are shaped cylindrically and are disposed concentrically relative to one another.

8. A motor vehicle, comprising:
an internal combustion engine;
an exhaust system;
a cooling circuit; and
at least one thermal generator having a plurality of thermoelectric devices according to claim 1;
said at least one first flow duct being connected to said exhaust system and said at least one second flow duct being connected to said cooling circuit.

9. A method for manufacturing a thermoelectric device, the method comprising the following steps:
providing a first carrier layer composed of an alloy containing a proportion of nickel of at least 9.0% by weight, a proportion of silicon of at most 1.0% by weight and at least one element from the group consisting of manganese, chromium, carbon, molybdenum, cobalt, aluminum, titanium, copper, niobium and iron;
providing a first electrical insulation layer for the first carrier layer;
providing a second carrier layer composed of an alloy having a proportion of nickel of between 9.0% by weight and 11.0% by weight, a proportion of copper of between 17.0% by weight and 19.0% by weight, a proportion of iron of at most 1.0% by weight, a proportion of carbon of at most 0.1% by weight, a proportion of silicon of at most 0.25% by weight and a remainder composed of manganese;
providing a second electrical insulation layer for the second carrier layer;
placing a plurality of p-doped and n-doped semiconductor elements between the first carrier layer and the second carrier layer; and
mounting the first carrier layer and the second carrier layer with the semiconductor elements disposed therebetween.

10. A method for manufacturing a thermoelectric device, the method comprising the following steps:
providing a first carrier layer composed of an alloy having a proportion of nickel of at least 32.0% by weight, a proportion of manganese of at most 1.0% by weight and containing no copper;
providing a first electrical insulation layer for the first carrier layer;
providing a second carrier layer composed of an alloy having a proportion of nickel of between 9.0% by weight and 11.0% by weight, a proportion of copper of between 17.0% by weight and 19.0% by weight, a proportion of iron of at most 1.0% by weight, a proportion of carbon of at most 0.1% by weight, a proportion of silicon of at most 0.25% by weight and a remainder composed of manganese;
providing a second electrical insulation layer for the second carrier layer;
placing a plurality of p-doped and n-doped semiconductor elements between the first carrier layer and the second carrier layer; and
mounting the first carrier layer and the second carrier layer with the semiconductor elements disposed therebetween.
